(19) United States
(12) Patent Application Publication
(10) Pub. No.: US 2006/0001041 A1
(43) Pub. Date: Jan. 5, 2006

(54) Organic light emitting device

(75) Inventor: Chao-Chi Peng, Tainan Hsien (TW)

Correspondence Address: CHRISTENSEN, O'CONNOR, JOHNSON, KINDNESS, PLLC, 1420 FIFTH AVENUE, SUITE 2800, SEATTLE, WA, 98101-2347, US

(73) Assignee: Lightronik Technology Inc.

(21) Appl. No.: 10/883,384

(22) Filed: Jul. 1, 2004

(51) Int. Cl. H01L 33/00

(52) U.S. Cl. 257/103; 257/99

(57) ABSTRACT

An organic light emitting device includes a substrate, an array of organic light emitting diodes mounted on the substrate, a cover disposed over the organic light emitting diodes and having a light transmittable region confronting the array of the organic light emitting diodes and an encompassing region around the light transmittable region, an outer sealing band surrounding the organic light emitting diodes and connected sealingly to the cover and the substrate, and an outer moisture absorbent disposed between the array of the organic light emitting diodes and the outer sealing band.

### BACKGROUND OF THE INVENTION

1. Field of the Invention

This invention relates to an organic light emitting device, more particularly to an organic light emitting device with at least one moisture absorbent around a light transmittable region of a cover.

2. Description of the Related Art

FIG. 1 illustrates a conventional organic light emitting device that includes a substrate 21, an array of organic light emitting diodes (OLED) 22 mounted on the substrate 21, and a cover 24 that covers sealingly the OLEDs 22 through a sealing band 23 so as to define a closed space 20 thereamong and so as to prevent oxygen and moisture from entering into the closed space 20. A moisture absorbent 25 is disposed securely in a recess 241 in the cover 24, which spans an area aligned with and covering the array of the OLEDs 22, for absorbing moisture in the closed space 20 so as to prevent damage to the OLEDs 20 as a result of the presence of moisture in the closed space 20.

Formation of the recess 241 in the cover 24 is normally conducted by sand blasting techniques or etching techniques. As a consequence, the transmittance of the cover 24 at the area where the recess 241 is formed is significantly decreased. Moreover, since the moisture absorbent 25 confronts the array of the OLEDs 22, a portion of the light emitted by the OLEDs 22 is undesirably reflected by the moisture absorbent 25.

### SUMMARY OF THE INVENTION

The object of the present invention is to provide an organic light emitting device that is capable of overcoming the aforesaid drawbacks associated with the prior art.

According to this invention, an organic light emitting device comprises: a substrate having a diode-mounting region and a surrounding region around the diode-mounting region; an array of organic light emitting diodes mounted on the diode-mounting region of the substrate; a cover disposed over the organic light emitting diodes and having a light transmittable region corresponding to and confronting the diode-mounting region of the substrate, and an encompassing region around the light transmittable region and corresponding to and confronting the surrounding region of the substrate; an outer sealing band surrounding the organic light emitting diodes and connected sealingly to the encompassing region of the cover and the surrounding region of the substrate so as to cooperate with the substrate and the cover to define a closed space thereamong and so as to seal the organic light emitting diodes in the closed space; and an outer moisture absorbent disposed between the array of the organic light emitting diodes and the outer sealing band within the closed space for absorbing moisture in the closed space.

### BRIEF DESCRIPTION OF THE DRAWINGS

Other features and advantages of the present invention will become apparent in the following detailed description of the preferred embodiments of the invention, with reference to the accompanying drawings, in which:

FIG. 1 is a schematic sectional view of a conventional organic light emitting device;

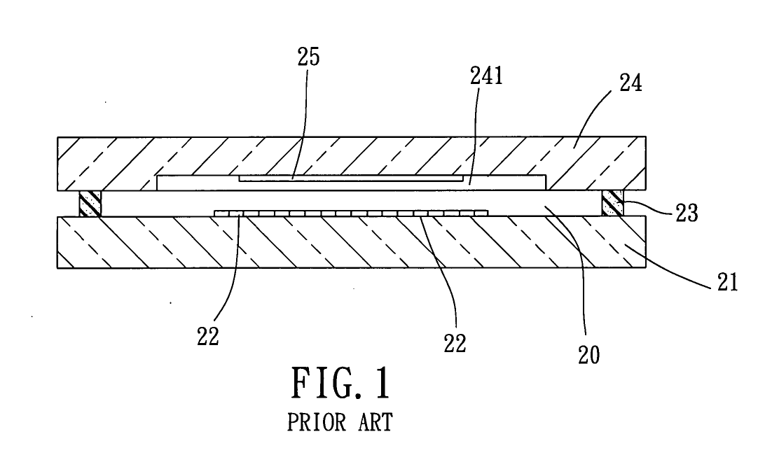

FIG. 2 is a schematic sectional view of the first preferred embodiment of an organic light emitting device according to this invention;

FIG. 3 is a schematic sectional view taken along lines III-III in FIG. 2;

FIG. 4 is a schematic sectional view of the second preferred embodiment of the organic light emitting device according to this invention;

FIG. 5 is a schematic sectional view taken along lines V-V in FIG. 4;

FIG. 6 is a schematic sectional view of the third preferred embodiment of this invention;

FIG. 7 is a schematic sectional view of the fourth preferred embodiment of the organic light emitting device according to this invention; and

FIG. 8 is a schematic sectional view taken along lines VIII-VIII in FIG. 7.

### DETAILED DESCRIPTION OF THE PREFERRED EMBODIMENTS

Before the present invention is described in greater detail, it should be noted that same reference numerals have been used to denote like elements throughout the specification.

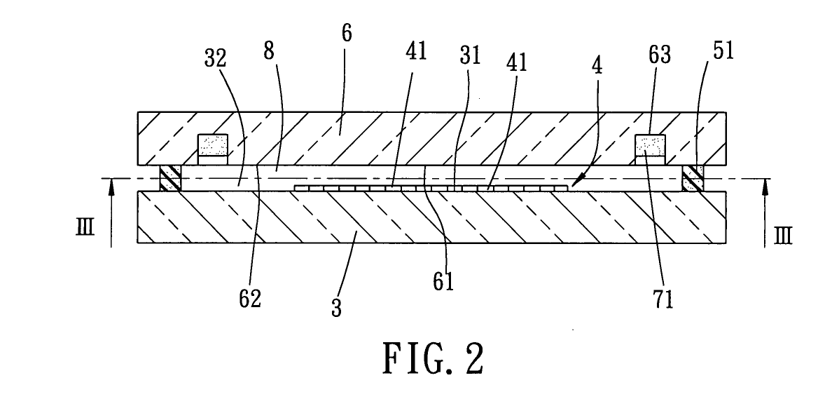

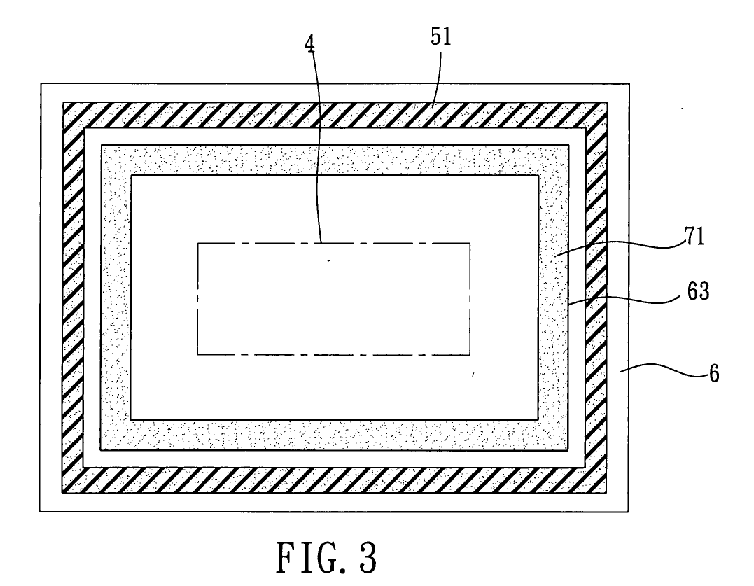

FIGS. 2 and 3 illustrate the first preferred embodiment of an organic light emitting device according to the present invention.

The organic light emitting device includes: a substrate 3 having a diode-mounting region 31 and a surrounding region 32 around the diode-mounting region 31; an array 4 of organic light emitting diodes 41 mounted on the diode-mounting region 31 of the substrate 3; a cover 6 disposed over the organic light emitting diodes 41 and having a light transmittable region 61 corresponding to and confronting the diode-mounting region 31 of the substrate 3, and an encompassing region 62 around the light transmittable region 61 and corresponding to and confronting the surrounding region 32 of the substrate 3; an outer sealing band 51 surrounding the organic light emitting diodes 41 and connected sealingly to the encompassing region 62 of the cover 6 and the surrounding region 32 of the substrate 3 so as to cooperate with the substrate 3 and the cover 6 to define a closed space 8 thereamong and so as to seal the organic light emitting diodes 41 in the closed space 8; and an outer moisture absorbent 71 disposed between the array 4 of the organic light emitting diodes 41 and the outer sealing band 51 within the closed space 8 for absorbing moisture in the closed space 8.

In this embodiment, the encompassing region 62 of the cover 6 is formed with an outer retaining groove 63 that surrounds the light transmittable region 61 of the cover 6. The outer moisture absorbent 71 is mounted securely in and extends along the outer retaining groove 63.

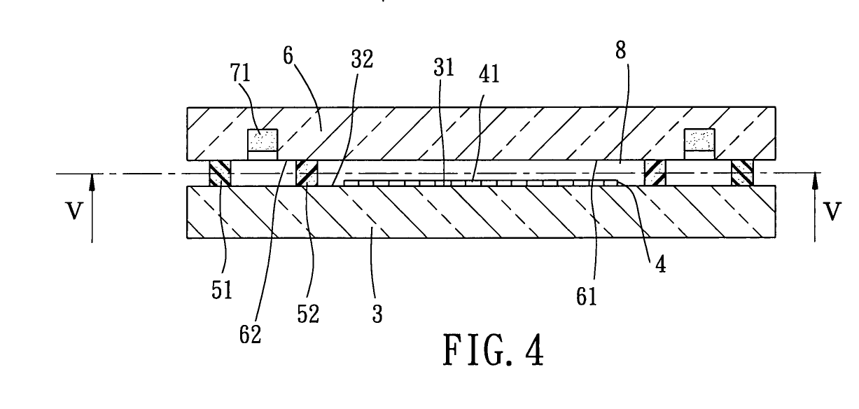

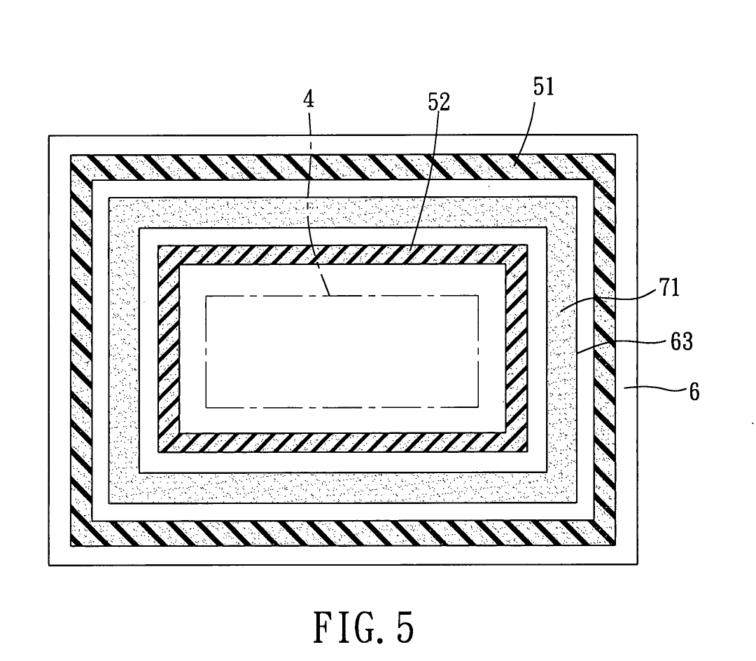

FIGS. 4 and 5 illustrate the second preferred embodiment of the organic light emitting device according to this invention. The organic light emitting device of this embodiment differs from the previous embodiment in that it further includes an inner sealing band 52 that surrounds the organic light emitting diodes 41, that is disposed between the outer moisture absorbent 71 and the array 4 of the organic light emitting diodes 41, and that is connected sealingly to the encompassing region 62 of the cover 6 and the surrounding region 32 of the substrate 3 so as to enhance the sealing effect of the closed space 8.

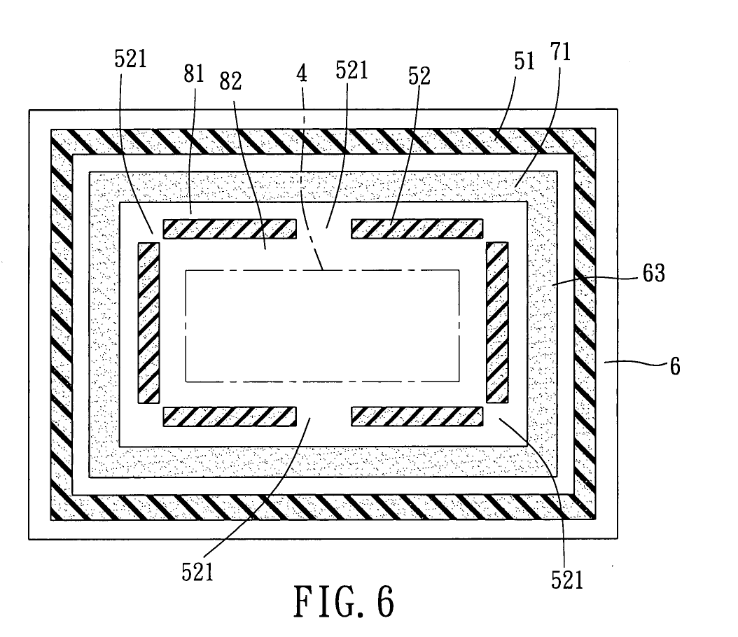

FIG. 6 illustrate the third preferred embodiment of the organic light emitting device according to this invention. The organic light emitting device of this embodiment differs from the second preferred embodiment in that the inner sealing band 52 cooperates with the outer moisture absorbent 71 to define a first space 81 therebetween, cooperates with the array 4 of the organic light emitting diodes 41 to define a second space 82 therebetween, and is formed with a plurality of passages 521 in fluid communication with the first and second spaces 81, 82.

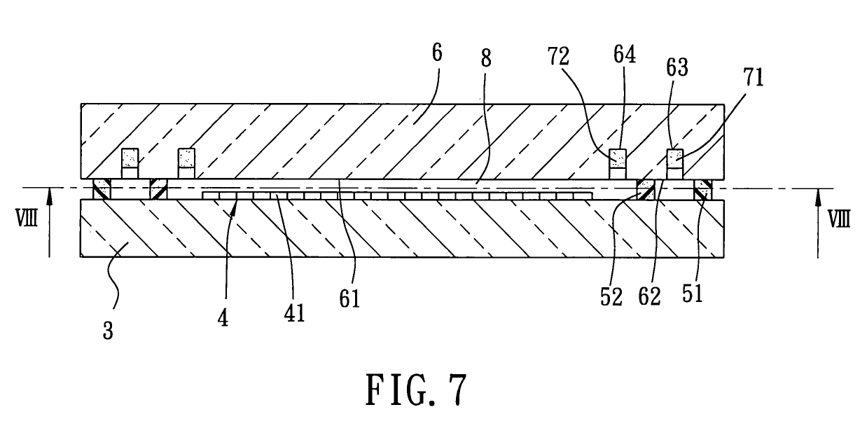

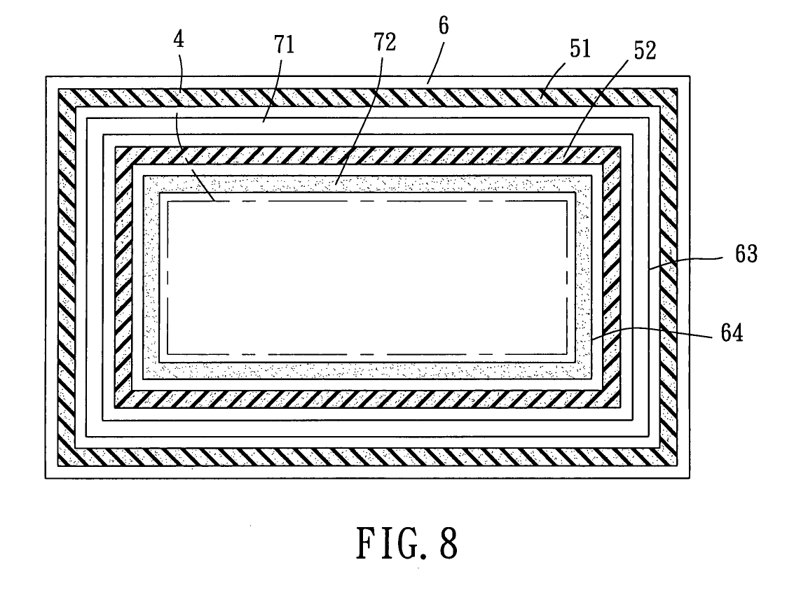

FIGS. 7 and 8 illustrate the fourth preferred embodiment of the organic light emitting device according to this invention. The organic light emitting device of this embodiment differs from the second preferred embodiment in that the encompassing region 62 of the cover 6 is further formed with an inner retaining groove 64 surrounding the light transmittable region 61 of the cover 6 and disposed between the inner sealing band 52 and the array 4 of the organic light emitting diodes 41. An inner moisture absorbent 72 is mounted securely in and extends along the inner retaining groove 64 in the cover 6 so as to enhance the absorbing of moisture in the closed space 8.

Preferably, the inner and outer moisture absorbents 72, 71 are made from a material selected from the group consisting of CaO, BaO, CaCl₂, CaH₂, NaH, CaSO₄, CaCO₃, MgSO₄, Na₂SO₄, Ca₂SO₄, and SrO.

Preferably, the cover 6 and the substrate 3 are made from a transparent material selected from the group consisting of glass and plastics.

Preferably, the inner and outer sealing bands 52, 51 are made from epoxy resin.

By positioning the outer moisture absorbent 71 at a position offset from the array 4 of the organic light emitting diodes 41, the aforesaid drawbacks associated with the prior art can be eliminated.

While the present invention has been described in connection with what is considered the most practical and preferred embodiments, it is understood that this invention is not limited to the disclosed embodiments but is intended to cover various arrangements included within the spirit and scope of the broadest interpretations and equivalent arrangements.

I claim:

1. An organic light emitting device comprising:
a substrate having a diode-mounting region and a surrounding region around said diode-mounting region;
an array of organic light emitting diodes mounted on said diode-mounting region of said substrate;
a cover disposed over said organic light emitting diodes and having a light transmittable region corresponding to and confronting said diode-mounting region of said substrate, and an encompassing region around said light transmittable region and corresponding to and confronting said surrounding region of said substrate;
an outer sealing band surrounding said organic light emitting diodes and connected sealingly to said encompassing region of said cover and said surrounding region of said substrate so as to cooperate with said substrate and said cover to define a closed space thereamong and so as to seal said organic light emitting diodes in said closed space; and
an outer moisture absorbent disposed between said array of said organic light emitting diodes and said outer sealing band within said closed space for absorbing moisture in said closed space.

2. The organic light emitting device of claim 1, wherein said encompassing region of said cover is formed with an outer retaining groove that surrounds said light transmittable region of said cover, said outer moisture absorbent being mounted securely in and extending along said outer retaining groove.

3. The organic light emitting device of claim 2, further comprising an inner sealing band that surrounds said organic light emitting diodes, that is disposed between said outer moisture absorbent and said array of said organic light emitting diodes, and that is connected sealingly to said encompassing region of said cover and said surrounding region of said substrate.

4. The organic light emitting device of claim 2, further comprising an inner sealing band that surrounds said organic light emitting diodes, that is disposed between said outer moisture absorbent and said array of said organic light emitting diodes, that is connected sealingly to said encompassing region of said cover and said surrounding region of said substrate, that cooperates with said outer moisture absorbent to define a first space therebetween, that cooperates with said array of said organic light emitting diodes to define a second space therebetween, and that is formed with a plurality of passages in fluid communication with said first and second spaces.

5. The organic light emitting device of claim 3, wherein said encompassing region of said cover is further formed with an inner retaining groove that surrounds said light transmittable region of said cover, and that is disposed between said inner sealing band and said array of said organic light emitting diodes, said organic light emitting device further comprising an inner moisture absorbent that is mounted securely in and that extends along said inner retaining groove.

6. The organic light emitting device of claim 1, wherein said outer moisture absorbent is made from a material selected from the group consisting of CaO, BaO, CaCl₂, CaH₂, NaH, CaSO₄, CaCO₃, MgSO₄, Na₂SO₄, Ca₂SO₄, and SrO.

7. The organic light emitting device of claim 1, wherein said cover is made from a transparent material selected from the group consisting of glass and plastics.

8. The organic light emitting device of claim 1, wherein said substrate is made from a transparent material selected from the group consisting of glass and plastics.

9. The organic light emitting device of claim 1, wherein said outer sealing band is made from epoxy resin.
